(19) United States
(12) Patent Application Publication
(10) Pub. No.: US 2024/0113195 A1
(43) Pub. Date: Apr. 4, 2024

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Jia-Ni YU, New Taipei City (TW); Lung-Kun CHU, New Taipei City (TW); Chun-Fu LU, Hsinchu (TW); Chung-Wei HSU, Baoshan Township (TW); Mao-Lin HUANG, Hsinchu City (TW); Kuo-Cheng CHIANG, Zhubei City (TW); Chih-Hao WANG, Baoshan Township (TW)

(73) Assignee: Taiwan Semiconductor Manufacturing Company, Ltd., Hsinchu (TW)

(21) Appl. No.: 18/172,703

(22) Filed: Feb. 22, 2023

Related U.S. Application Data
(60) Provisional application No. 63/411,816, filed on Sep. 30, 2022.

(51) Int. Cl. H01L 29/423; H01L 29/06; H01L 29/66; H01L 29/775; H01L 29/786

(52) U.S. Cl. CPC H01L 29/42392; H01L 29/0642; H01L 29/66439; H01L 29/775; H01L 29/78696; B82Y 40/00; H01L 29/0673; H01L 29/66545

(57) ABSTRACT

Semiconductor structures and methods for forming the same are provided. The semiconductor structure includes a plurality of first nanostructures formed over a substrate, and a dielectric wall adjacent to the first nanostructures. The semiconductor structure also includes a first liner layer between the first nanostructures and the dielectric wall, and the first liner layer is in direct contact with the dielectric wall. The semiconductor structure also includes a gate structure surrounding the first nanostructures, and the first liner layer is in direct contact with a portion of the gate structure.

### CROSS REFERENCE TO RELATED APPLICATIONS

This application claims the benefit of U.S. Provisional Application No. 63/411,816 filed on Sep. 30, 2022, and the entirety of which is incorporated by reference herein.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1I show perspective views of intermediate stages of manufacturing a semiconductor structure, in accordance with some embodiments.

FIGS. 2A-1 to 2N-1 show top views of various stages of manufacturing the semiconductor structure shown along plane Y-Y′ in FIGS. 2A-2-2N-2, in accordance with some embodiments.

FIGS. 2A-2-2N-2 shows a cross-sectional representation of the semiconductor device structure along line A-A′ shown in FIG. 1I.

FIG. 2A-3 shows a cross-sectional representation of the semiconductor device structure 100a along line X₁-X₁′ in FIG. 2A-1.

FIG. 2A-4 shows a cross-sectional representation of the semiconductor device structure along line X₂-X₂′ in FIG. 2A-1.

FIG. 2B-3 shows a cross-sectional representation of the semiconductor device structure along line X₁-X₁′ in FIG. 2B-1.

FIG. 2B-4 shows a cross-sectional representation of the semiconductor device structure along line X₂-X₂′ in FIG. 2B-1.

FIG. 2E-3 shows a cross-sectional representation of the semiconductor device structure along line X₁-X₁′ in FIG. 2E-1.

FIG. 2F-3 shows a cross-sectional representation of the semiconductor device structure along line X₁-X₁′ in FIG. 2F-1.

FIG. 2G-3 shows a cross-sectional representation of the semiconductor device structure along line X₁-X₁′ in FIG. 2G-1.

FIG. 2H-3 shows a cross-sectional representation of the semiconductor device structure along line X₁-X₁′ in FIG. 2H-1.

FIG. 2H-4 shows a cross-sectional representation of the semiconductor device structure along line X₂-X₂′ in FIG. 2H-1.

FIG. 2I-3 shows a cross-sectional representation of the semiconductor device structure along line X₁-X₁′ in FIG. 2I-1.

FIG. 2I-4 shows a cross-sectional representation of the semiconductor device structure along line X₂-X₂′ in FIG. 2I-1.

FIG. 2N′-1 shows a top-view of a semiconductor device structure, in accordance with some embodiments of the disclosure.

FIG. 3 shows an enlarged cross-sectional representation of the semiconductor device structure in region A of FIG. 2K-2, in accordance with some embodiments of the disclosure.

FIG. 4A show top view of a semiconductor structure shown along plane Y-Y′ in FIG. 4B, in accordance with some embodiments.

FIG. 4B shows a cross-sectional representation of the semiconductor device structure along line Y-Y′ in FIG. 4A.

FIG. 5A show top view of a semiconductor structure shown along plane Y-Y′ in FIG. 5B, in accordance with some embodiments.

FIG. 5B shows a cross-sectional representation of the semiconductor device structure along line Y-Y′ in FIG. 5A.

FIG. 6A show top view of a semiconductor structure shown along plane Y-Y′ in FIG. 6B, in accordance with some embodiments.

FIG. 6B shows a cross-sectional representation of the semiconductor device structure along line Y-Y′ in FIG. 6A.

FIG. 7A show top view of a semiconductor structure shown along plane Y-Y′ in FIG. 7B, in accordance with some embodiments.

FIG. 7B shows a cross-sectional representation of the semiconductor device structure along line Y-Y′ in FIG. 7A.

FIG. 8A show top view of a semiconductor structure shown along plane Y-Y′ in FIG. 8B, in accordance with some embodiments.

FIG. 8B shows a cross-sectional representation of the semiconductor device structure along line Y-Y′ in FIG. 8A.

FIG. 9A show top view of a semiconductor structure shown along plane Y-Y′ in FIG. 9B, in accordance with some embodiments.

FIG. 9B shows a cross-sectional representation of the semiconductor device structure along line Y-Y′ in FIG. 9A.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned using any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned using any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a plurality of first nanostructures and a plurality of second nanostructures. The first nanostructures and the second nanostructures are wrapped by the gate structure. A portion of the first nanostructures and a portion of the second nanostructures are wrapped in an S/D structure. A dielectric wall is between the first nanostructures and the second nanostructures. A remaining liner layer is between the dielectric wall and the first nanostructures and the second nanostructures. The space between the first nanostructures and the second nanostructures is filled with the dielectric wall to reduce the parasitic capacitance of the semiconductor structure. In addition, the remaining liner layer can also reduce the parasitic capacitance of the semiconductor structure. Therefore, the performance of the semiconductor structure is improved. Source/drain (S/D) region(s) or the S/D structures may refer to a source or a drain, individually or collectively dependent upon the context.

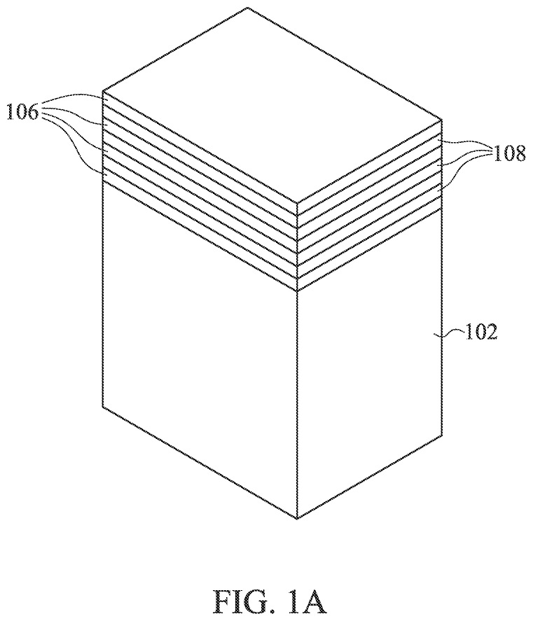

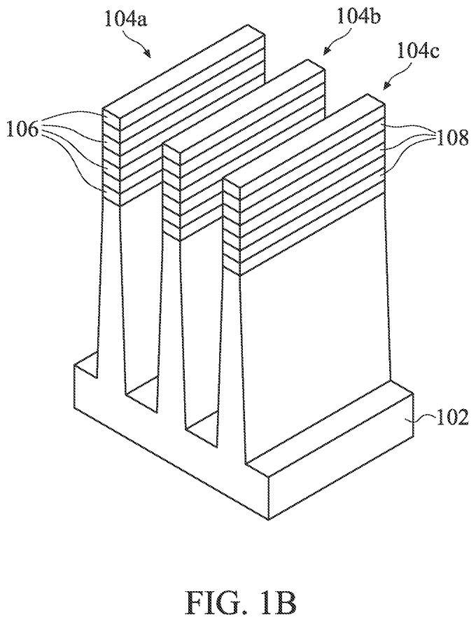

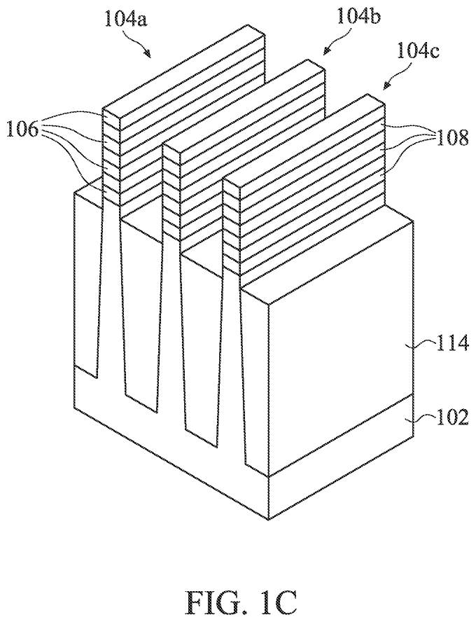

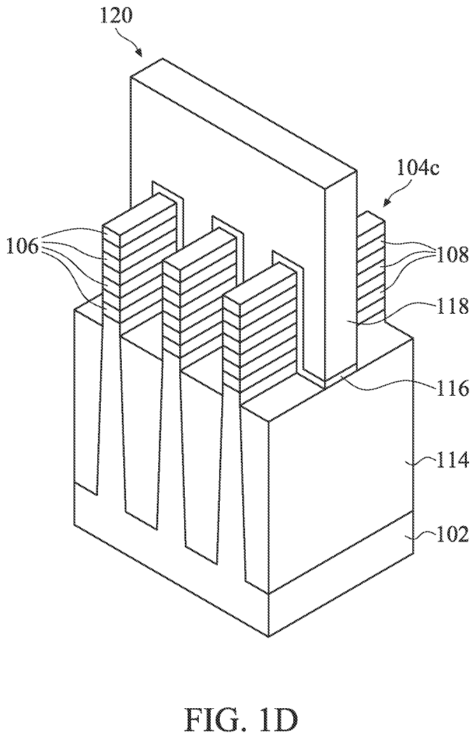

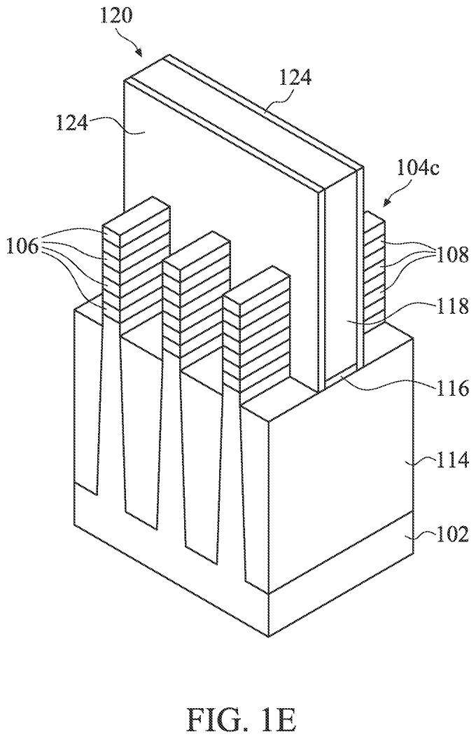

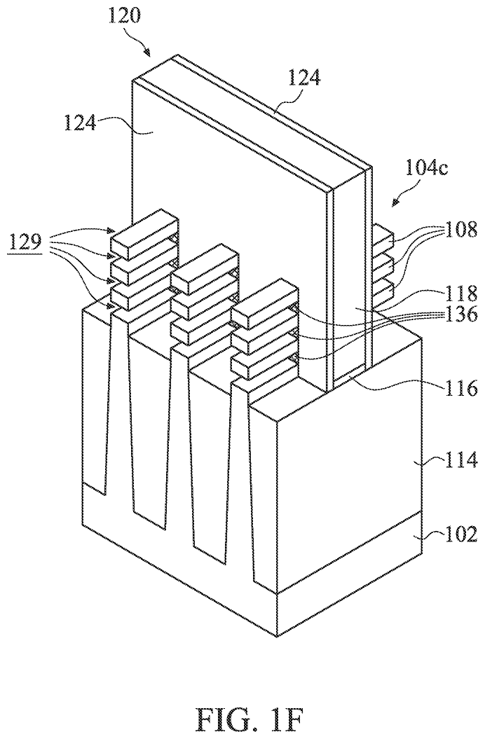

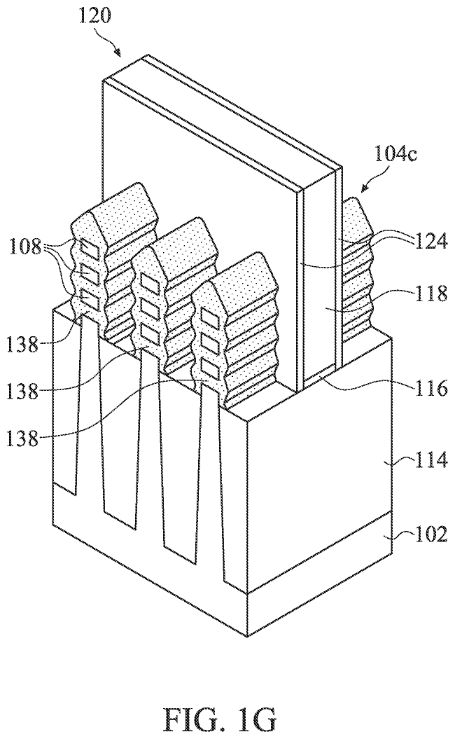

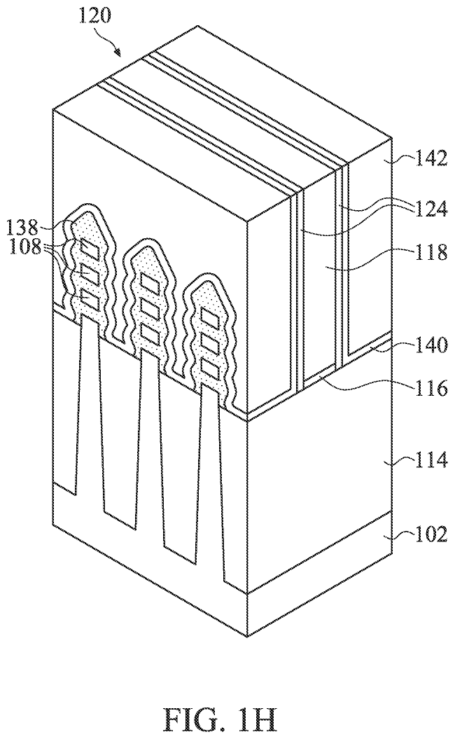

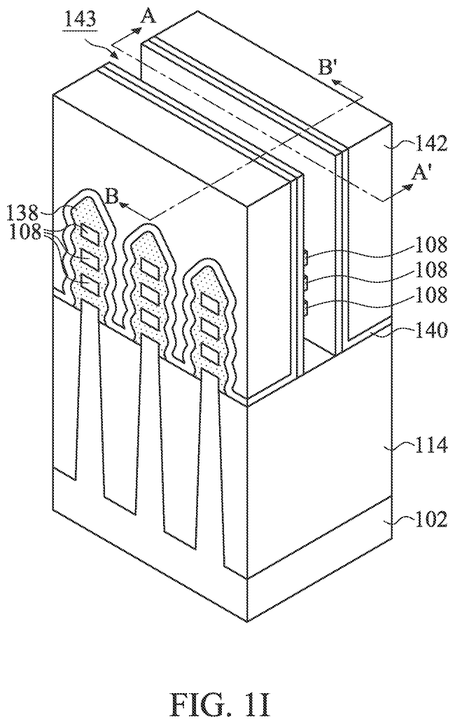

FIGS. 1A to 1I show perspective views of intermediate stages of manufacturing a semiconductor structure 100a, in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiments, the first semiconductor layers 106 and the second semiconductor layers 108 independently include silicon (Si), germanium (Ge), silicon germanium (Si₁₋ₓGeₓ, 0.1<x<0.7, the value x is the atomic percentage of germanium (Ge) in the silicon germanium), indium arsenide (InAs), indium gallium arsenide (InGaAs), indium antimonide (InSb), or another applicable material.

The first semiconductor layers 106 and the second semiconductor layers 108 are made of different materials having different lattice constants. In some embodiments, the first semiconductor layer 106 is made of silicon (Si), and the second semiconductor layer 108 is made of silicon germanium (Si₁₋ₓGeₓ, 0.1<x<0.7). In some other embodiments, the first semiconductor layer 106 is made of silicon germanium (Si₁₋ₓGeₓ, 0.1<x<0.7), and the second semiconductor layer 108 is made of silicon (Si).

It should be noted that although four first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

Next, as shown in FIG. 1B, the first semiconductor material layers 106 and the second semiconductor material layers 108 are patterned to form a semiconductor material stack over a fin structure 105, in accordance with some embodiments. The semiconductor material stack includes a first stack structure 104a, a second stack structure 104b and a third stack structure 104c above the fin structure 105.

In some embodiments, the patterning process includes forming a mask structure over the semiconductor material stack, and etching the semiconductor material stack and the underlying substrate 102 through the mask structure. In some embodiments, the mask structure is a multilayer structure including a pad oxide layer and a nitride layer formed over the pad oxide layer. The pad oxide layer may be made of silicon oxide, which is formed by thermal oxidation or chemical vapor deposition (CVD), and the nitride layer may be made of silicon nitride, which is formed by chemical vapor deposition (CVD), such as low-temperature chemical vapor deposition (LPCVD) or plasma-enhanced CVD (PECVD).

Afterwards, as shown in FIG. 1C, an isolation structure 114 is formed over the substrate 102, in accordance with some embodiments. The isolation structure 114 may be a shallow trench isolation (STI) structure surrounding the first stack structure 104a, the second stack structure 104b and the third stack structure 104c. The top portions of the first stack structure 104a, the second stack structure 104b and the third stack structure 104c are above the isolation structure 114.

Next, as shown in FIG. 1D, a dummy gate dielectric layer 116 is formed over the fin structure 110, and then a dummy gate electrode layer 118 is formed on the dummy gate dielectric layer 116, in accordance with some embodiments. Afterwards, the dummy gate dielectric layer 116 and the dummy gate electrode layer 118 are patterned using a patterning process. The dummy gate structure 120 is constructed by the dummy gate dielectric layer 116 and the dummy gate electrode layer 118.

The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process includes a dry etching process or a wet etching process.

The dummy gate electrode layer 118 is formed to partially cover and to extend across the first stack structure 104a, the second stack structure 104b and the third stack structure 104c. In some embodiments, the dummy gate electrode layer 118 wraps around the first stack structure 104a, the second stack structure 104b and the third stack structure 104c. The dummy gate dielectric layer 116 may be made of or include silicon oxide. In some embodiments, the dummy gate dielectric layers 116 is formed using a deposition process, such as chemical vapor deposition (CVD) process, physical vapor deposition (PVD) process, atomic layer deposition (ALD) process, another applicable process, or a combination thereof.

In some embodiments, the dummy gate electrode layer 118 is made of polycrystalline-silicon (poly-Si) or poly-crystalline silicon-germanium (poly-SiGe). In some embodiments, the dummy gate electrode layer 118 is formed using a deposition process, such as chemical vapor deposition (CVD) process, physical vapor deposition (PVD) process, atomic layer deposition (ALD) process, another applicable process, or a combination thereof.

Afterwards, as shown in FIG. 1E, a gate spacer layer 124 is formed on opposite sidewall surfaces of the dummy gate electrode layer 118 and over the dummy gate dielectric layer 116, in accordance with some embodiments. The gate spacer layer 124 can provide more protection to the dummy gate structure 120 during subsequent processes.

In some embodiments, the gate spacer layer 124 is made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the gate spacer layer 124 is formed using a deposition process, such as chemical vapor deposition (CVD) process, physical vapor deposition (PVD) process, atomic layer deposition (ALD) process, another applicable process, or a combination thereof.

Next, as shown in FIG. 1F, a portion of the first semiconductor layers 106 is removed to form an S/D trench 129, in accordance with some embodiments. The S/D trench 129 is between two adjacent second semiconductor layers 108.

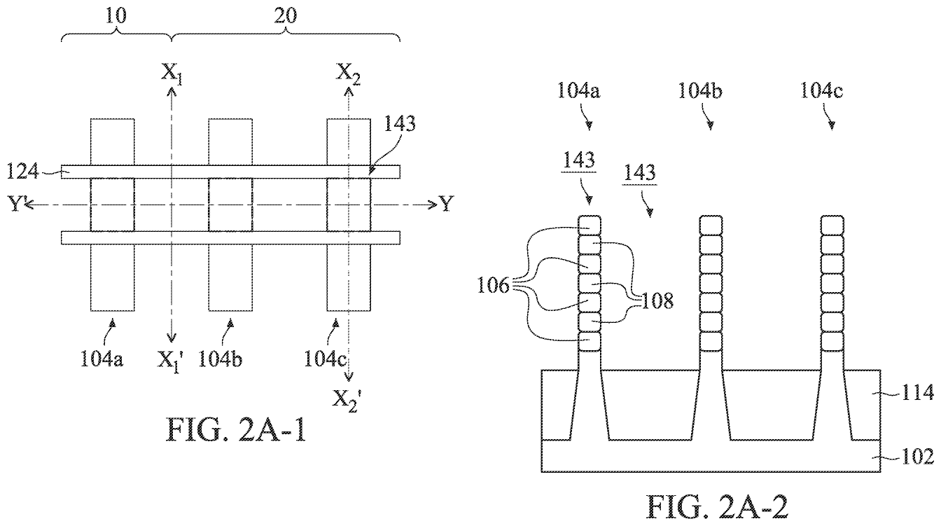

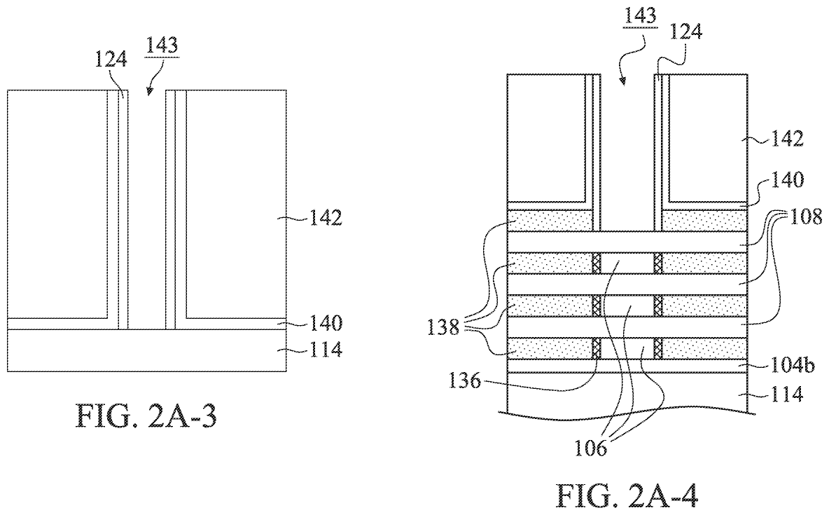

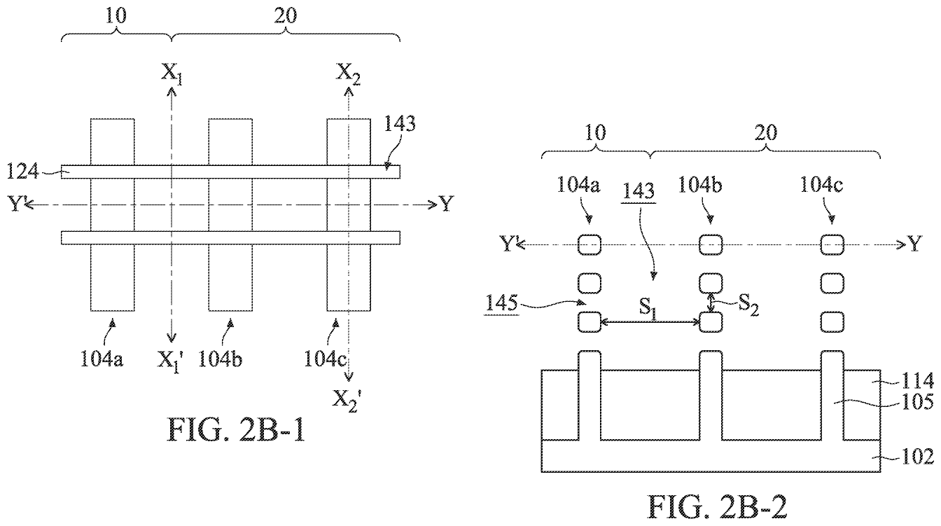

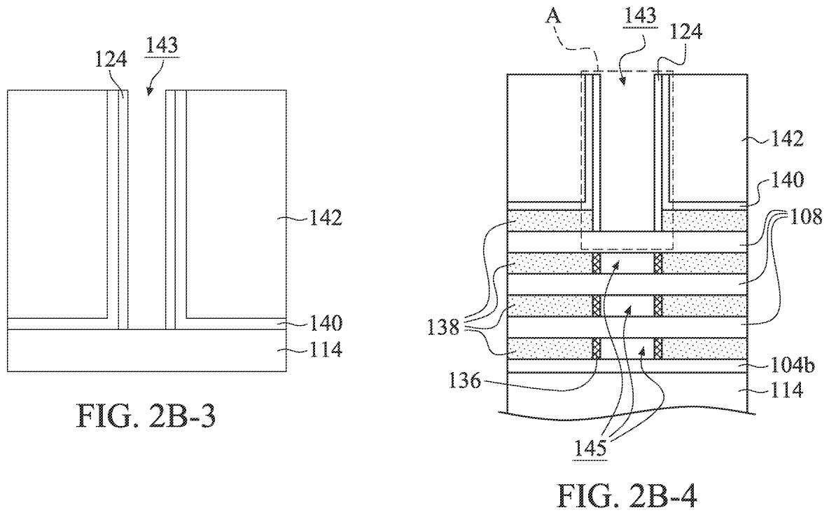

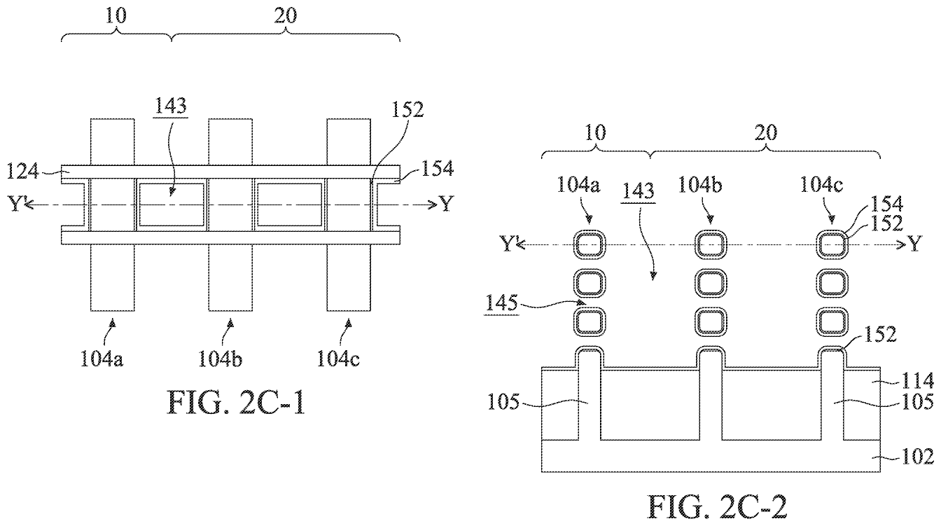

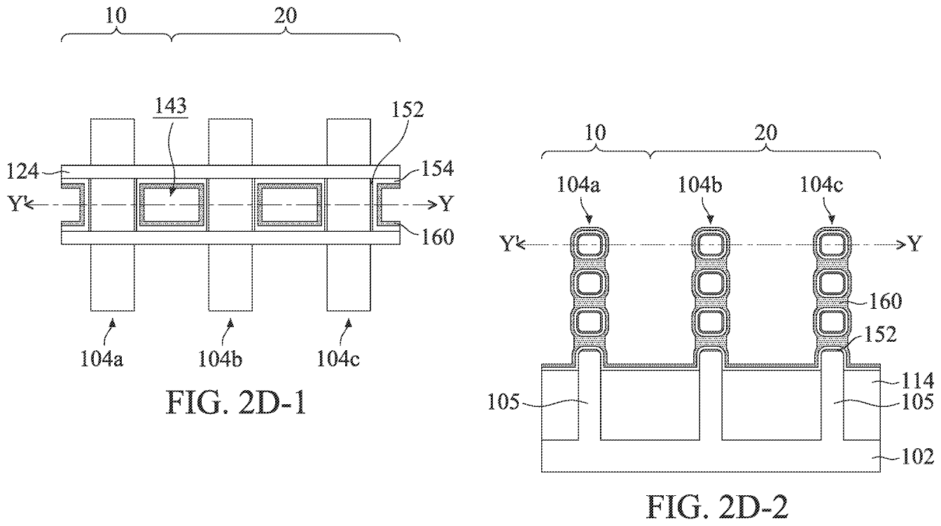

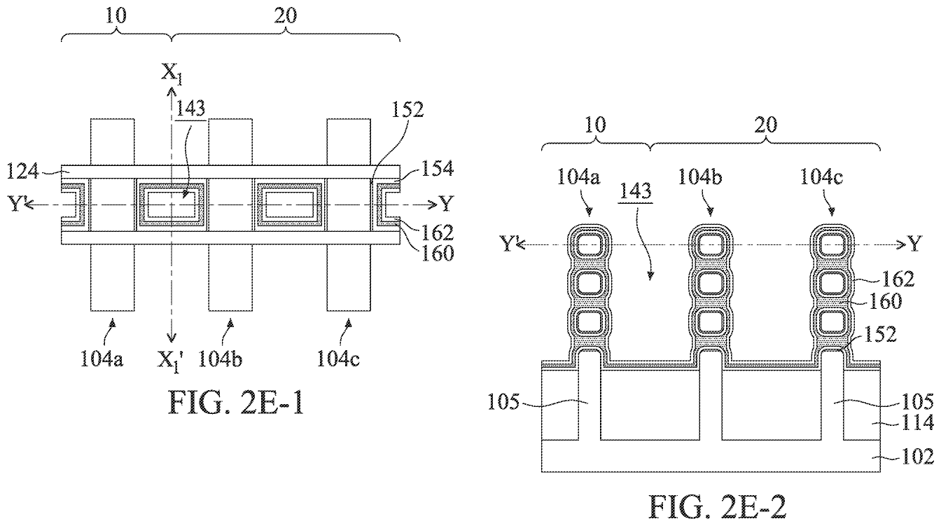

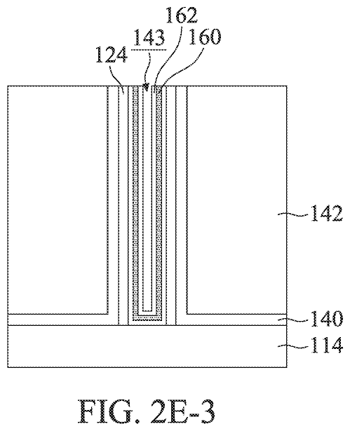

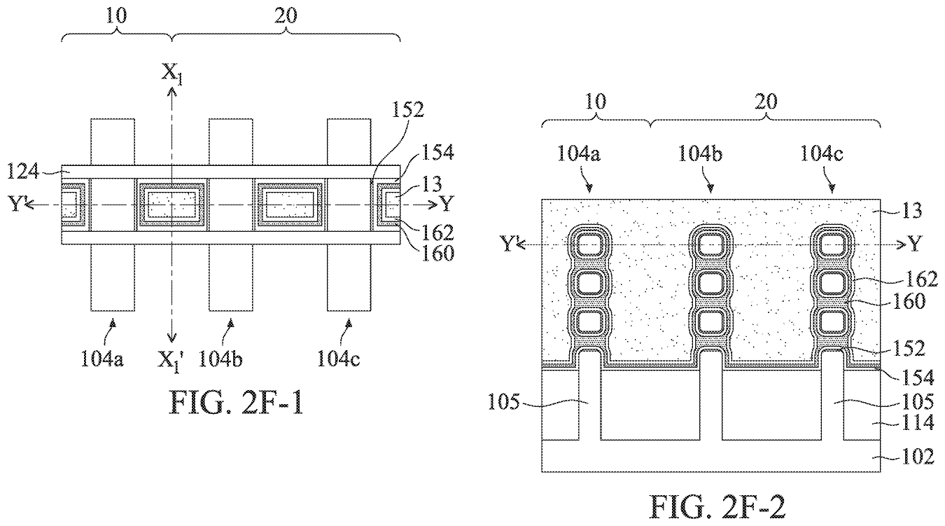

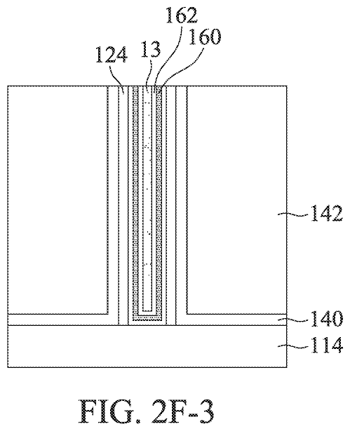

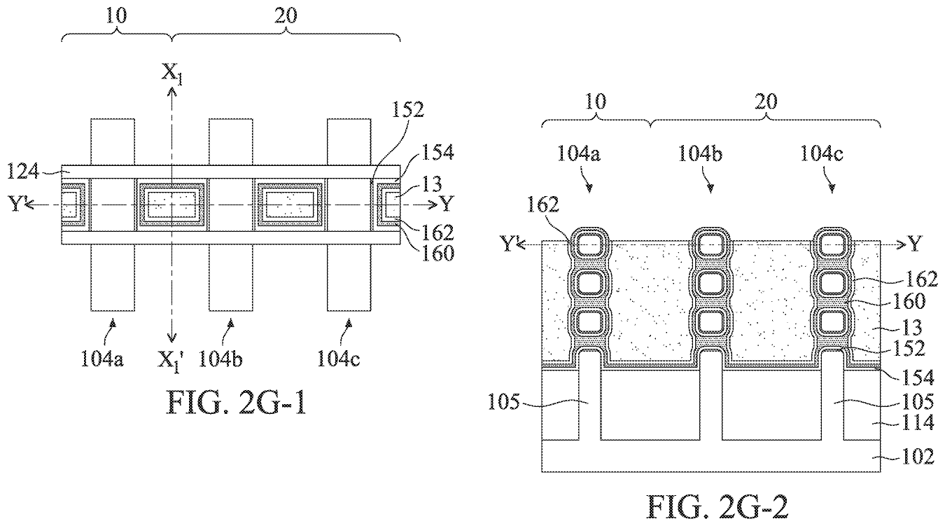

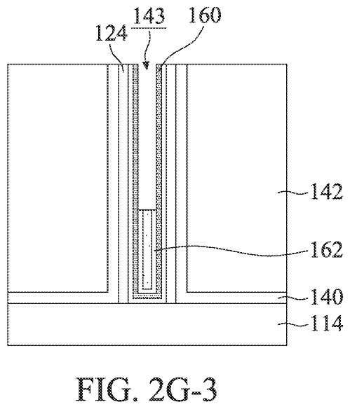

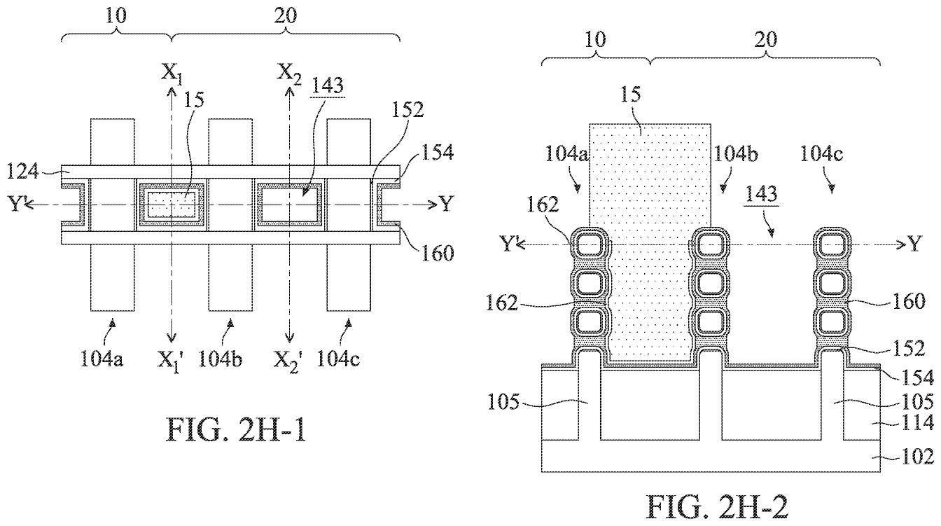

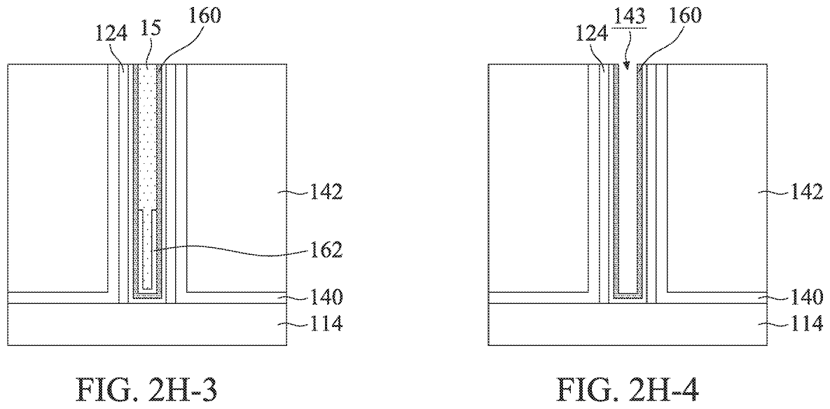

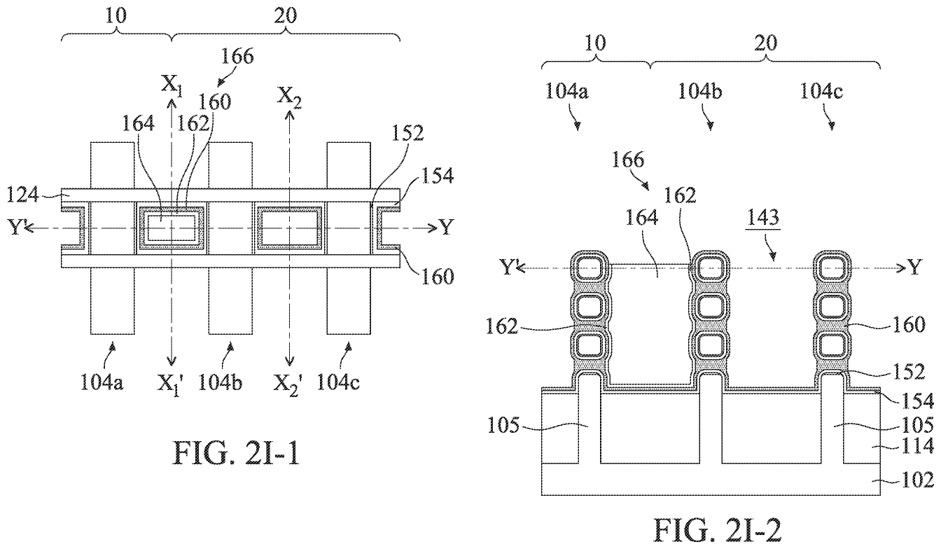

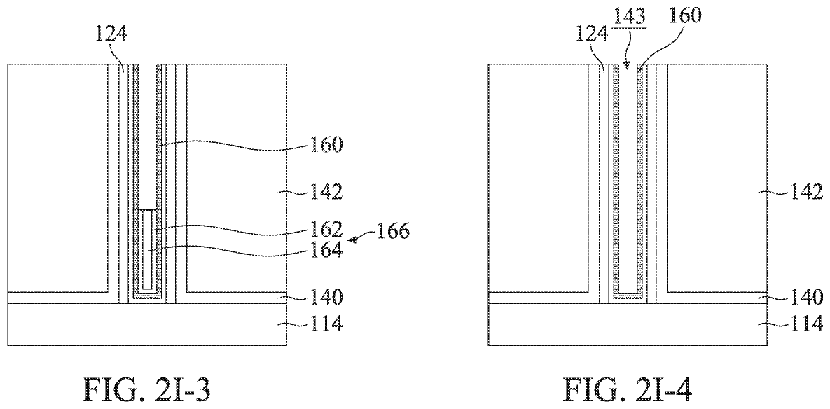

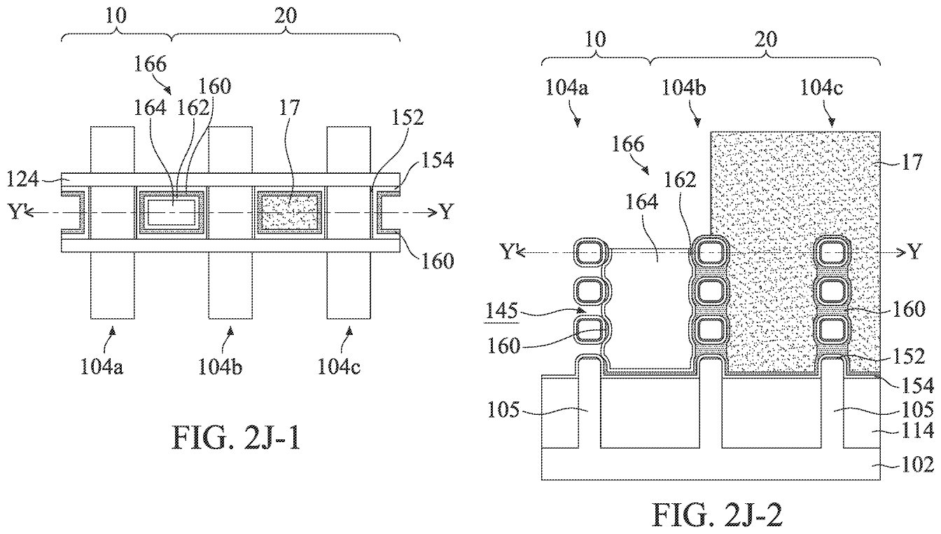

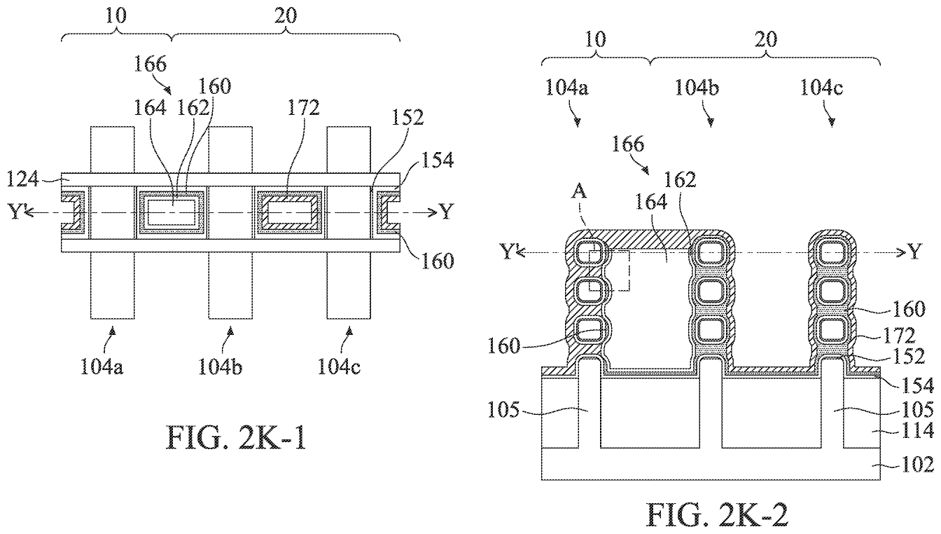

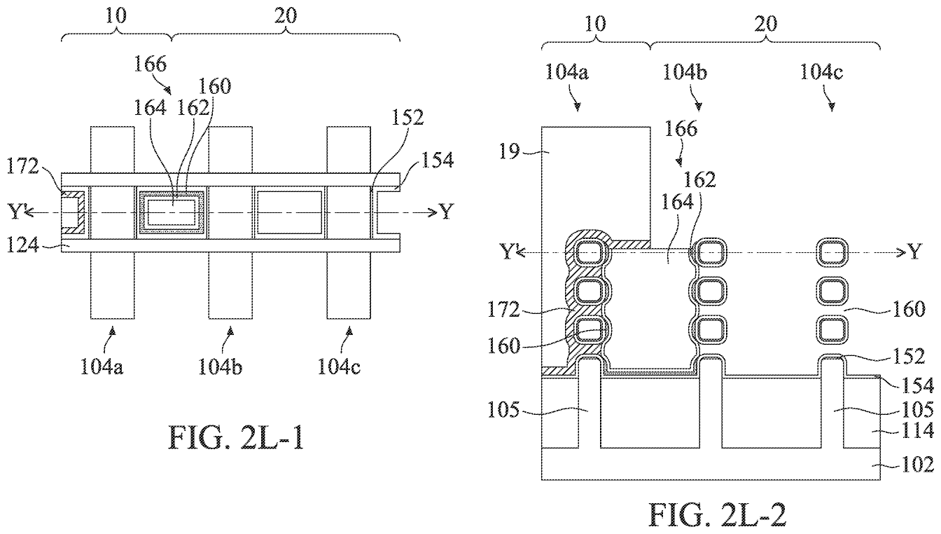

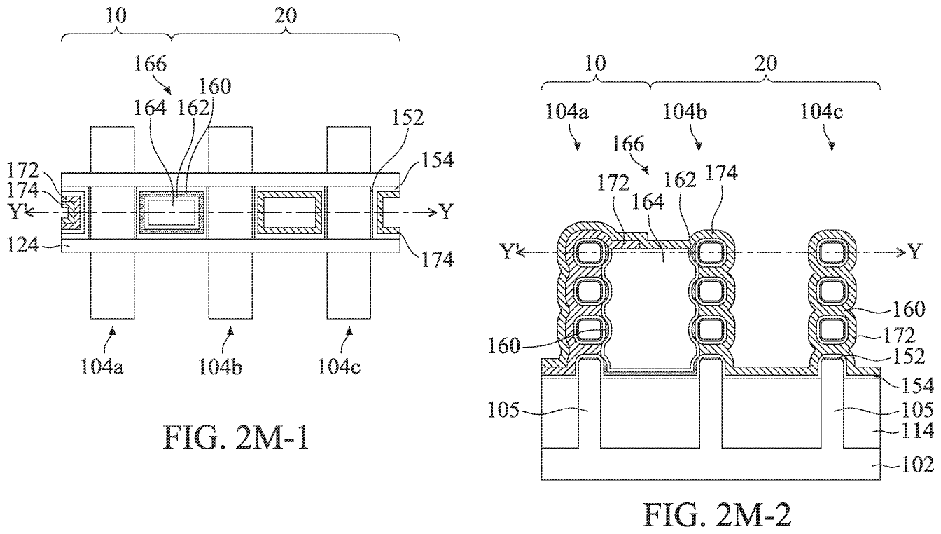

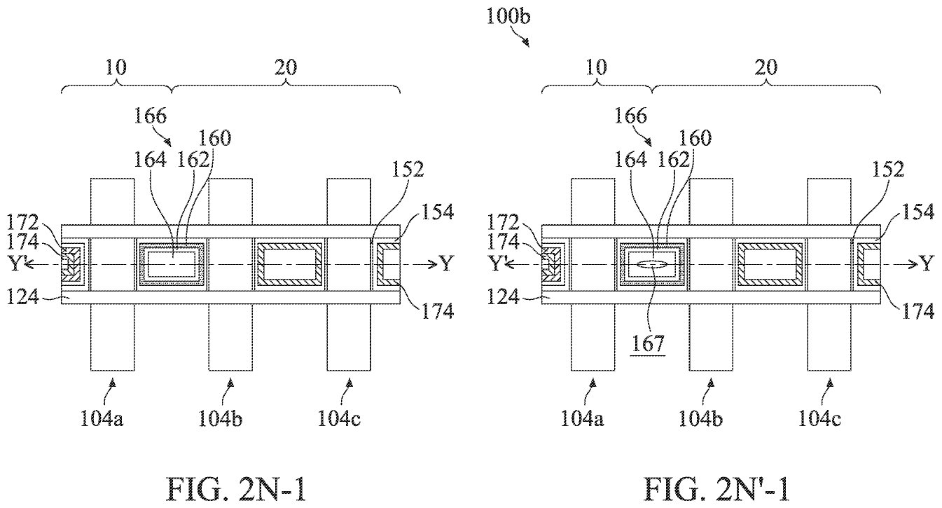

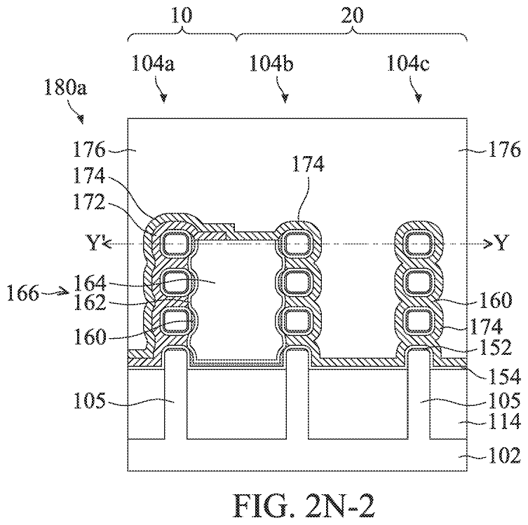

Next, another portion of the first semiconductor layers 106 directly below the gate spacer layer 124 is removed to form a cavity (not shown), and the cavity is exposed by the S/D trench 129. Afterwards, an inner spacer layer 136 is formed in the cavity. The inner spacer layer 136 is directly below the gate spacer layer 124. The inner spacer layer 136 is used to be as a barrier between an S/D structure 138 (formed later, FIG. 1G) and a gate structure 180a/180b (formed later, as shown in FIG. 2N-2). The inner spacer layer 136 can reduce the parasitic capacitance between the S/D structure 138 (formed later, FIG. 1G) and the gate structure 180a/180b (formed later, as shown in FIG. 2N-2). Afterwards, as shown in FIG. 1F, an S/D structure 138 is formed in the S/D trench 129, in accordance with some embodiments. The S/D structure 138 is in direct contact with the inner spacer layer 136.

The S/D structure 138 may include silicon germanium (SiGe), indium arsenide (InAs), indium gallium arsenide (InGaAs), indium antimonide (InSb), gallium arsenide (GaAs), gallium antimonide (GaSb), indium aluminum phosphide (InAlP), indium phosphide (InP), or a combination thereof. The S/D structure 138 may doped with one or more dopants. In some embodiments, the S/D structure 138 is silicon (Si) doped with phosphorus (P), arsenic (As), antimony (Sb), or another applicable dopant. Alternatively, the S/D structure 138 is silicon germanium (SiGe) doped with boron (B) or another applicable dopant.

In some embodiments, the S/D structure 138 is formed using an epitaxy or epitaxial (epi) process. The epi process may include a selective epitaxial growth (SEG) process, CVD deposition techniques (e.g., vapor-phase epitaxy (VPE) and/or ultra-high vacuum CVD (UHV-CVD)), molecular beam epitaxy, or another suitable epi process. The source/drain (S/D) region(s) or S/D structures may refer to a source or a drain, individually or collectively dependent upon the context.

Next, as shown in FIG. 1H, a contact etch stop layer (CESL) 140 is formed over the S/D structures 138, and an inter-layer dielectric (ILD) layer 142 is formed over the CESL 140, in accordance with some embodiments. Next, a portion of the ILD layer 142 is removed to expose the top surface of the dummy gate electrode layer 118. In some embodiments, the portion of the ILD layer 142 is removed using a planarizing process, a chemical mechanical polishing (CMP) process.

In some embodiments, the CESL 140 is made of silicon nitride, silicon oxynitride, or another applicable material. The CESL 140 may be formed using a plasma enhanced chemical vapor deposition (CVD) process, low pressure CVD process, atomic layer deposition (ALD) process, or another applicable processes.

The ILD layer 142 may include multilayers made of multiple dielectric materials, such as silicon oxide, silicon nitride, silicon oxynitride, phosphosilicate glass (PSG), borophosphosilicate glass (BPSG), low-k dielectric material, or another applicable dielectric material. Examples of low-k dielectric materials include, but are not limited to, fluorinated silica glass (FSG), carbon doped silicon oxide, amorphous fluorinated carbon, parylene, bis-benzocyclobutenes (BCB), and polyimide. The ILD layer 142 may be formed using a chemical vapor deposition (CVD) process, physical vapor deposition (PVD) process, atomic layer deposition (ALD) process, spin-on coating process, or another applicable process.

Afterwards, as shown in FIG. 1I, the dummy gate structure 120 is removed to form a trench 143 in the ILD layer 142, in accordance with some embodiments. The dummy gate dielectric layer 116 and the dummy gate electrode layer 118 are removed in an etching process, such as a dry etching process or a wet etching process.

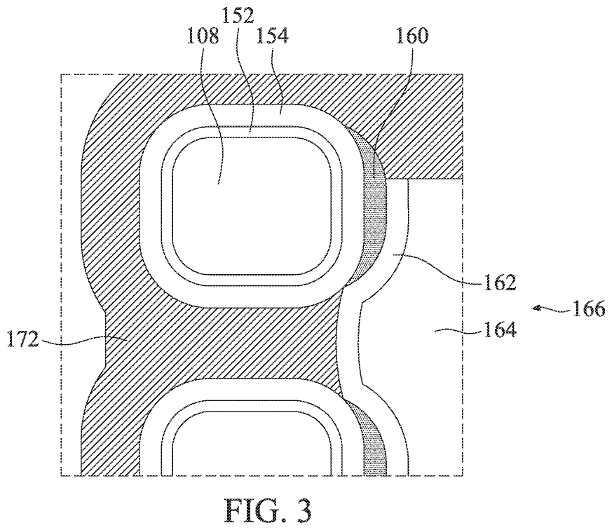

FIGS. 2A-1 to 2N-1 show top views of various stages of manufacturing the semiconductor structure 100a shown along plane Y-Y′ in FIGS. 2A-2-2N-2, in accordance with some embodiments. FIGS. 2A-2-2N-2 shows a cross-sectional representation of the semiconductor device structure 100a along line A-A′ shown in FIG. 1I. FIG. 2A-3 shows a cross-sectional representation of the semiconductor device structure 100a along line X₁-X₁′ in FIG. 2A-1. FIG. 2A-4 shows a cross-sectional representation of the semiconductor device structure 100a along line X₂-X₂′ in FIG. 2A-1. In addition, FIG. 2A-4 shows a cross-sectional representation of the semiconductor device structure 100a along line B-B′ shown in FIG. 1I, in accordance with some embodiments of the disclosure.

As shown in FIGS. 2A-1, 2A-2, 2A-3 and 2A-4, the first semiconductor layers 106 and the second semiconductor layers 108 are exposed by the trench 143. In addition, the gate spacer layer 124 is exposed by the trench 143.

FIG. 2B-3 shows a cross-sectional representation of the semiconductor device structure 100a along line X₁-X₁′ in FIG. 2B-1. FIG. 2B-4 shows a cross-sectional representation of the semiconductor device structure 100a along line X₂-X₂′ in FIG. 2B-1.

Next, as shown in FIGS. 2B-1, 2B-2, 2B-3 and 2B-4, the first semiconductor layers 106 are removed to form a number of gaps 145, in accordance with some embodiments of the disclosure. The first stack structure 104a is formed in a first region 10, and the second stack structure 104b and the third stack structure 104c are formed in a second region 20.

Each of the gaps 145 is formed between two adjacent second semiconductor layers 108. Since the first semiconductor layers 106 and the second semiconductor layers 108 are made of different materials, they have different etching selectivity. Therefore, the first semiconductor layers 106 are removed, but the second semiconductor layers 108 are left.

The remaining second semiconductor layers 108 are used to as channel region of the semiconductor device structure 100a. In some embodiments, the second semiconductor layers 108 may be referred to as “nanostructures”, “nanowires”, or “nanosheets”. Therefore, the first stack structure 104a, the second stack structure 104b and the third stack structure 104c respectively includes a number of nanostructures stacked in a vertical direction.

There is a first space S₁ between the first stack structure 104a and the second stack structure 104b. In some embodiments, the first space S₁ is in a range from about 20 nm to about 60 nm. There is a second space S₂ between two adjacent nanostructures 108 in the first stack structure 104a. In some embodiments, the second space S₂ is in a range from about 9 nm to about 12 nm.

Afterwards, as shown in FIGS. 2C-1, 2C-2, an interfacial layer 152 and a gate dielectric layer 154 are formed over the nanostructures 108, in accordance with some embodiments of the disclosure. The trench 143 and the gap 145 are not completely filled with the interfacial layer 152 and the gate dielectric layer 154. The gate dielectric layer 154 has a ring-shaped structure when seen from a top-view, as shown in FIG. 2C-1. In addition, the gate dielectric layer 154 is confined between the gate spacer layer 124 when seen from a top-view, as shown in FIG. 2N-1. The gate dielectric layer 154 is in direct contact with the gate spacer layer 124.

In some embodiments, the interfacial layer 152 is oxide layer formed around the nanostructures 108. In some embodiments, the interfacial layer 152 is formed by performing a thermal process. In some embodiments, the gate dielectric layer 154 are formed over the interfacial layer 152, so that the nanostructures 108 are surrounded (e.g. wrapped) by the interfacial layer 152 and gate dielectric layer 154.

In some embodiments, the gate dielectric layers 154 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, another suitable high-k dielectric material, or a combination thereof. The high-k dielectric material refers to a dielectric constant that is greater than the dielectric constant of silicon oxide (e.g. greater than about 3.9). In some embodiments, the gate dielectric layers 154 are formed using chemical vapor deposition (CVD), atomic layer deposition (ALD), another applicable method, or a combination thereof.

In some embodiments, the interfacial layer 152 has a thickness in a range from about 1 nm to about 1.5 nm. In some embodiments, the gate dielectric layer 154 has a thickness in a range from about 1 nm to about 2.5 nm.

Next, as shown in FIGS. 2D-1 and 2D-2, a liner layer 160 is formed over the gate dielectric layer 154, and the spaces between two adjacent nanostructures 108 and the isolation structure 114, in accordance with some embodiments of the disclosure. The gap 145 is filled with the interfacial layer 152, the gate dielectric layer 154 and the liner layer 160. The liner layer 160 acts as a sacrificial layer which will be removed in the following steps. The gaps 145 between two adjacent nanostructures 108 will fill with the gate structure 180a/180b (formed later, as shown in FIG. 2N-2) by replacing the liner layer 160 with the gate material in the following steps.

The liner layer 160 has a ring-shaped structure when seen from a top-view, as shown in FIG. 2D-1. In addition, the liner layer 160 is confined between the gate spacer layer 124 and enclosed by the gate dielectric layer 154 when seen from a top-view, as shown in FIG. 2N-1.

In some embodiments, the liner layer 160 is made of AlOx, AiN, SiN, SiOCN, or another applicable material. In some embodiments, the liner layer 160 is formed by chemical vapor deposition (CVD), atomic layer deposition (ALD), another applicable method, or a combination thereof. In some embodiments, the liner layer 160 has a thickness in a range from about 1 nm to about 2 nm.

FIG. 2E-3 shows a cross-sectional representation of the semiconductor device structure 100a along line X₁-X₁′ in FIG. 2E-1.

Afterwards, as shown in FIGS. 2E-1, 2E-2 and 2E-3, a spacer layer 162 is formed over the liner layer 160, in accordance with some embodiments of the disclosure. The trench 143 is not completely filled with the spacer layer 162. The spacer layer 162 has a ring-shaped structure when seen from a top-view, as shown in FIG. 2E-1.

It should be noted that the spacer layer 162 and the liner layer 160 are made of different materials. The spacer layer 162 and the liner layer 160 have different etching rates. The liner layer 160 has a higher etching selectivity with respect to the spacer layer 162. In some embodiments, the liner layer 160 is not removed or rare removed when the spacer layer 162 is removed.

In some embodiments, the spacer layer 162 is made of oxide, silicon oxide, SiN, SiOCN, SiCN, SiOC, or another applicable material. In some embodiments, the spacer layer 162 is formed by chemical vapor deposition (CVD), atomic layer deposition (ALD), another applicable method, or a combination thereof.

FIG. 2F-3 shows a cross-sectional representation of the semiconductor device structure 100a along line X₁-X₁′ in FIG. 2F-1.

Next, as shown in FIGS. 2F-1, 2F-2 and 2F-3, a mask layer 13 is formed in the trench 143 and over the spacer layer 162, in accordance with some embodiments of the disclosure. The mask layer 13 is used to define the location and the height of the spacer layer 162 in the following steps.

In some embodiments, the mask layer 13 is made of titanium nitride (TiN), silicon nitride (SiN), silicon oxynitride (SiON), silicon carbon nitride (SiCN), or a combination thereof. In some embodiments, the mask layer 13 is formed by using a chemical vapor deposition (CVD) process, physical vapor deposition (PVD) process, atomic layer deposition (ALD) process, another applicable process, or a combination thereof.

FIG. 2G-3 shows a cross-sectional representation of the semiconductor device structure 100a along line X₁-X₁′ in FIG. 2G-1.

Afterwards, as shown in FIGS. 2G-1, 2G-2 and 2G-3, a portion of the mask layer 13 is removed to expose the topmost nanostructure 108, and a top portion of the spacer layer 162 is removed, in accordance with some embodiments of the disclosure. As a result, the top surface of the liner layer 160 is exposed. The remaining spacer layer 162 is lower than the top surface of the liner layer 160. As mentioned above, the liner layer 160 and the spacer layer 162 have different etching rates, and therefore the liner layer 160 is not removed or rare removed when the spacer layer 162 is removed.

In some embodiments, the top portion of the mask layer 13 is removed by using a dry etching process. In some embodiments, the dry etching process includes using N₂ gas or H₂ gas. In some embodiments, the top portion of the spacer layer 162 is removed using a dry etching process. In some embodiments, the dry etching process includes using fluorine (F)-containing gas.

FIG. 2H-3 shows a cross-sectional representation of the semiconductor device structure 100a along line X₁-X₁′ in FIG. 2H-1. FIG. 2H-4 shows a cross-sectional representation of the semiconductor device structure 100a along line X₂-X₂′ in FIG. 2H-1.

Next, as shown in FIGS. 2H-1, 2H-2, 2H-3 and 2H-4, the mask layer 13 is removed, and another mask layer 15 is formed in the space between the first stack structure 104a and the second stack structure 104b, in accordance with some embodiments of the disclosure. The mask layer 15 is configured to define the location of a dielectric wall 166 (formed later).

A portion of the spacer layer 162 which is not covered by the mask layer 15 is removed. The remaining spacer layer 162 is at a region between the first stack structure 104a and the second stack structure 104b.

In some embodiments, the mask layer 15 is made of titanium nitride (TiN), silicon nitride (SiN), silicon oxynitride (SiON), silicon carbon nitride (SiCN), or a combination thereof. In some embodiments, the mask layer 15 is formed by using a chemical vapor deposition (CVD) process, physical vapor deposition (PVD) process, atomic layer deposition (ALD) process, another applicable process, or a combination thereof.

FIG. 2I-3 shows a cross-sectional representation of the semiconductor device structure 100a along line X₁-X₁′ in FIG. 2I-1. FIG. 2I-4 shows a cross-sectional representation of the semiconductor device structure 100a along line X₂-X₂′ in FIG. 2I-1.

Afterwards, as shown in FIGS. 2I-1 and 2I-2, the mask layer 15 is removed, and then a dielectric wall material 164 is formed on the remaining spacer layer 162, in accordance with some embodiments of the disclosure. A dielectric wall 166 is constructed by the dielectric wall material 164 and the spacer layer 162. The dielectric wall 166 is between the first stack structure 104a and the second stack structure 104b. The top surface of the dielectric wall 166 is lower than the top surface of the topmost nanostructure 108. In addition, the top surface of the dielectric wall 166 is lower than the top surface of the liner layer 160. The top surface of the topmost nanostructure 108 is exposed to perform the function of the channel layer.

In some embodiments, the dielectric wall material 164 and the spacer layer 162 are made of the same material. In some embodiments, the dielectric wall material 164 is made of oxide, silicon oxide, SiN, SiOCN, SiCN, SiOC, or another applicable material. In some other embodiments, the dielectric wall material 164 and the spacer layer 162 are made of different materials. In some embodiments, the dielectric wall material 164 is formed by chemical vapor deposition (CVD), atomic layer deposition (ALD), another applicable method, or a combination thereof.

The dielectric wall 166 is confined between the gate spacer layer 124 and enclosed by the liner layer 160 and the gate dielectric layer 154 when seen from a top-view, as shown in FIG. 2I-1. The dielectric wall 166 is isolated from the gate dielectric layer 154 by the liner layer 160. The dielectric wall 166 has a rectangular shape when seen from a top-view. The dielectric wall 166 may have different shapes, such as circular shape, when seen from a top-view.

Next, as shown in FIGS. 2J-1 and 2J-2, a mask layer 17 formed over the second stack structure 104b and the third stack structure 104c in the second region 20, in accordance with some embodiments of the disclosure. A portion of the dielectric wall 166 is exposed which is not covered by the mask layer 17. Next, a portion of the liner layer 160 is removed, but another portion of the liner layer 160 which is protected by the dielectric wall 166 is left. The remaining liner layer 160 is between the gate dielectric layer 154 over the first stack structure 104a and the dielectric wall 166. The remaining liner layer 160 can reduce the parasitic capacitance of the semiconductor structure 100a. The remaining liner layer 160 has a recessed top surface toward to the gate dielectric layer 154.

The remaining liner layer 160 is in direct contact with the gate dielectric layer 154 over the first stack structure 104a and the dielectric wall 166. The remaining liner layer 160 is between the dielectric wall 166 and the nanostructure 108 of the first stack structure 104a in the first region 10. The remaining liner layer 160 is at the end of the nanostructure (channel) 108 of the first stack structure 104a.

In some embodiments, the portion of the liner layer 160 is removed using a wet etching process. The gap 145 between two adjacent nanostructure 108 of the first stack structure 104a is exposed again after the wet etching process.

In some embodiments, the mask layer 17 is made of titanium nitride (TiN), silicon nitride (SiN), silicon oxynitride (SiON), silicon carbon nitride (SiCN), or a combination thereof. In some embodiments, the mask layer 17 is formed by using a chemical vapor deposition (CVD) process, physical vapor deposition (PVD) process, atomic layer deposition (ALD) process, another applicable process, or a combination thereof.

Afterwards, as shown in FIGS. 2K-1 and 2K-2, a first work function layer 172 is formed on the gate dielectric layer 154 in the first region 10, in accordance with some embodiments of the disclosure. In other words, the nanostructures (or channels) 108 are surrounded by the first work function layer 172. In addition, the first work function layer 172 extends to cover the top surface of the dielectric wall 166, and over the liner layer 160 on the second stack structure 104b in the second region 20. The first work function layer 172 is in direct contact with the top surface of the dielectric wall 166. The first work function layer 172 is configured to tune threshold voltage (Vt) of the semiconductor structure 100a.

In some embodiments, the first work function layer 172 is a n-type work function layer. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the first work function layer 172 is formed by chemical vapor deposition (CVD), atomic layer deposition (ALD), electroplating, another applicable method, or a combination thereof.

Next, as shown in FIGS. 2L-1 and 2L-2, a mask layer 19 formed over the first stack structure 104a in the first region 10, in accordance with some embodiments of the disclosure. A portion of the first work function layer 172 and a portion of the liner layer 160 which are not covered by the mask layer 19 are removed. As a result, a portion of the gate dielectric layer 154 over the second stack structure 104b and over the third stack structure 104c is exposed. The spaces between two adjacent nanostructures 108 of the second stack structure 104b and the third stack structure 104c are exposed.

It should be noted that a portion of the liner layer 160 is removed, but another portion of the liner layer 160 which is protected by the dielectric wall 166 is left. The remaining liner layer 160 is between and in direct contact with the gate dielectric layer 154 over the second stack structure 104b and the dielectric wall 166. The remaining liner layer 160 is between the dielectric wall 166 and the nanostructure 108 of the second stack structure 104b in the second region 20. The remaining liner layer 160 is at the end of the nanostructure (channel) 108 of the second stack structure 104b. The remaining liner layer 160 can reduce the parasitic capacitance of the semiconductor structure 100a. The remaining liner layer 160 has a recessed top surface toward to the gate dielectric layer 154.

In some embodiments, the mask layer 19 is made of titanium nitride (TiN), silicon nitride (SiN), silicon oxynitride (SiON), silicon carbon nitride (SiCN), or a combination thereof. In some embodiments, the mask layer 19 is formed by using a chemical vapor deposition (CVD) process, physical vapor deposition (PVD) process, atomic layer deposition (ALD) process, another applicable process, or a combination thereof.

Afterwards, as shown in FIGS. 2M-1 and 2M-2, a second work function layer 174 is formed over the first work function layer 172 in the first region 10, and over the gate dielectric layer 154 in the second region 20, in accordance with some embodiments of the disclosure. The second work function layer 174 is in direct contact with a portion of the dielectric wall 166. The second work function layer 174 is configured to tune threshold voltage (Vt) of the semiconductor structure 100a.

In some embodiments, the second work function layer 174 is made of p-work function layer. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof. In some embodiments, the second work function layer 174 is formed by chemical vapor deposition (CVD), atomic layer deposition (ALD), electroplating, another applicable method, or a combination thereof.

Next, as shown in FIGS. 2N-1 and 2N-2, a gate fill layer 176 is formed over the second work function layer 174, in accordance with some embodiments of the disclosure. The first gate structure 180a in the first region 10 is constructed by the interfacial layer 152, the gate dielectric layer 154, the first work function layer 172, the second work function layer 174 and the gate fill layer 176. The second gate structure 180b in the second region 20 is constructed by the interfacial layer 152, the gate dielectric layer 154, the second work function layer 174 and the gate fill layer 176. In some embodiments, the first gate structure 180a is an N-type field-effect transistor (NFET), and the second gate structure 180b is a P-type field-effect transistor (PFET).

In some embodiments, the gate fill layer 176 is made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate fill layer 176 is formed using chemical vapor deposition (CVD), atomic layer deposition (ALD), electroplating, another applicable method, or a combination thereof.

The dielectric wall 166 is between the first stack structure 104a in the first region 10 and the second stack structure 104b in the second region 20. If no dielectric wall 166 is between the first stack structure 104a and the second stack structure 104b, a gate structure will be in the space between the first stack structure 104a and the second stack structure 104b. The unwanted parasitic capacitance may occur between two adjacent stack structures. In order to reduce the unwanted parasitic capacitance, a portion of the gate structure is replaced by the dielectric wall 166 to reduce the volume of the gate structure. Therefore, the unwanted parasitic capacitance may be reduced, and the performance of the semiconductor structure 100a is improved.

The top surface of the dielectric wall 166 is lower than the top surface of the topmost nanostructure 108. The coverage of the first work function layer 172 or the second work function layer 174 is determined by the height of the dielectric wall 166.

The dielectric wall 166 is confined between the gate spacer layer 124 and enclosed by the liner layer 160 and the gate dielectric layer 154 when seen from a top-view, as shown in FIG. 2N-1. The dielectric wall 166 is confined between the space between the nanostructure (channel) 108 of the first stack structure 104a and the nanostructure (channel) 108 of the second stack structure 104b. The bottommost surface of the liner layer 160 is lower than the top surface of the fin structure 105. A portion of the liner layer 160 is directly below and in direct contact with the dielectric wall 166.

FIG. 2N′-1 shows a top-view of a semiconductor device structure 100b, in accordance with some embodiments of the disclosure. The semiconductor structure 100b of FIG. 2N′-1 includes elements that are similar to, or the same as, elements of the semiconductor structure 100a of FIG. 2N-1.

As shown in FIG. 2N′-1, a seam 167 is formed in the dielectric wall 166. The seam 167 is confined by the gate dielectric layer 154 and the gate spacer layer 124. The seam 167 is along the direction of gate structure 180a.

FIG. 3 shows an enlarged cross-sectional representation of the semiconductor device structure 100a in region A of FIG. 2K-2, in accordance with some embodiments of the disclosure. The remaining liner layer 160 is between and in direct contact with the gate dielectric layer 154 over the first stack structure 104a and the dielectric wall 166. The nanostructures (or channels) 108 are separated from the dielectric wall 166 by the gate dielectric layer 154 and the liner layer 160.

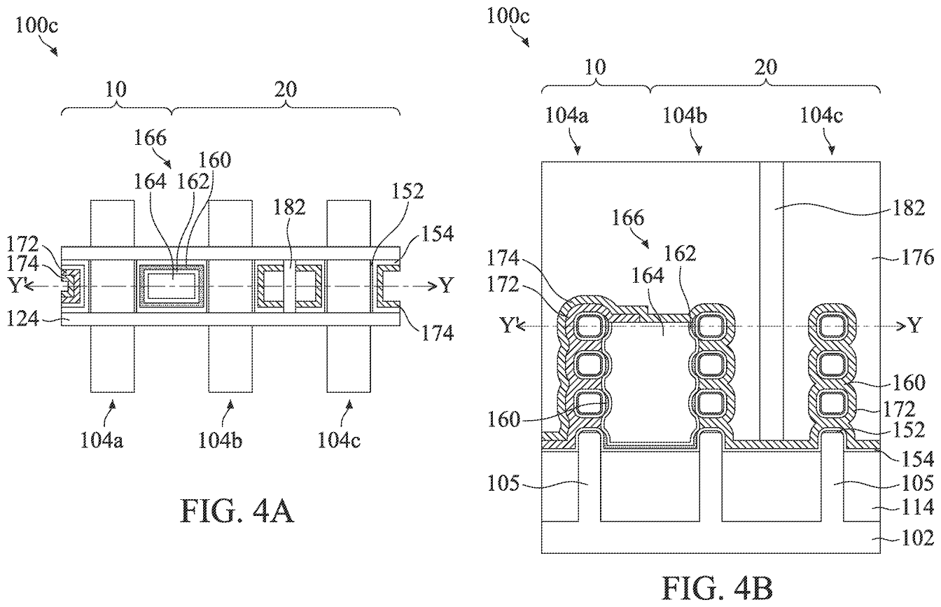

FIG. 4A show top view of a semiconductor structure 100c shown along plane Y-Y′ in FIG. 4B, in accordance with some embodiments. FIG. 4B shows a cross-sectional representation of the semiconductor device structure 100c along line Y-Y′ in FIG. 4A. The semiconductor structure 100c of FIGS. 4A-4B includes elements that are similar to, or the same as, elements of the semiconductor structure 100a of FIGS. 2A-2N-1 and 2A-2-2N-2.

As shown in FIGS. 4A and 4B, a deep isolation structure 182 is formed between the second stack structure 104b and the third stack structure 104c. The deep isolation structure 182 is configured to isolate the gate fill layer 176 over the second stack structure 104b and the gate fill layer 176 over the third stack structure 104c. The top surface of the deep isolation structure 182 is higher than the top surface of the topmost nanostructure (channel) 108.

In some embodiments, the bottom surface of the deep isolation structure 182 is lower than the top surface of the isolation structure 114. The bottom portion of the deep isolation structure 182 is embedded in the isolation structure 114. In some embodiments, the deep isolation structure 182 has a uniform width from top to bottom. In some embodiments, the deep isolation structure 182 has the top surface and the bottom surface, and the bottom width of the bottom surface is smaller than the top width of the top surface.

In some embodiments, the deep isolation structure 182 is made of dielectric material, such as oxide, silicon oxide, SiN, SiOCN, SiCN, SiOC, or another applicable material. In some embodiments, the deep isolation structure 182 is made of a high k dielectric material, such as HfO₂, ZrO₂, HfAlOₓ, HfSiOₓ, Al₂O₃, or the like. In some embodiments, the deep isolation structure 182 is formed by chemical vapor deposition (CVD), atomic layer deposition (ALD), another applicable method, or a combination thereof.

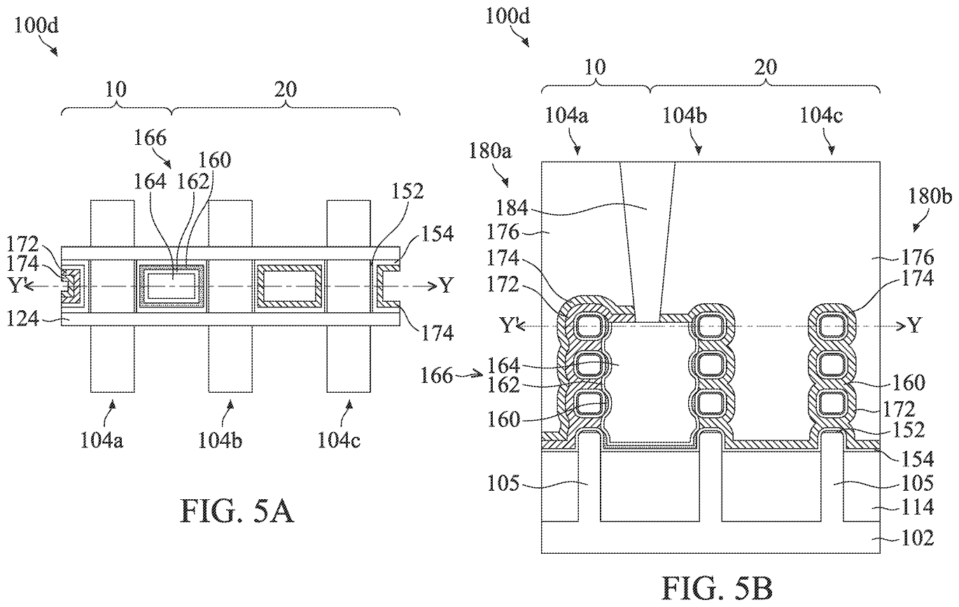

FIG. 5A show top view of a semiconductor structure 100d shown along plane Y-Y′ in FIG. 5B, in accordance with some embodiments. FIG. 5B shows a cross-sectional representation of the semiconductor device structure 100d along line Y-Y′ in FIG. 5A. The semiconductor structure 100d of FIGS. 5A-5B includes elements that are similar to, or the same as, elements of the semiconductor structure 100a of FIGS. 2A-2N-1 and 2A-2-2N-2.

As shown in FIGS. 5A and 5B, a cut gate structure 184 is formed between the first stack structure 104a and the second stack structure 104b, in accordance with some embodiments. More specifically, the first gate structure 180a is isolated from the second gate structure 180b by the dielectric wall 166 and the cut gate structure 184. The cut gate structure 184 is in direct contact with the dielectric wall 166 and the first work function layer 172 and the second work function layer 174. The bottom surface of the cut gate structure 184 is lower than the topmost surface of the topmost nanostructure (channel) 108. In addition, the bottom surface of the cut gate structure 184 is lower than the top surface of the dielectric wall 166. The top surface of the cut gate structure 184 is higher than the topmost surface of the topmost nanostructure (channel) 108. In some embodiments, the cut gate structure 184 has the top surface and the bottom surface, and the bottom width of the bottom surface is smaller than the top width of the top surface. In some embodiments, the cut gate structure 184 has uniform width from top to bottom.

In some embodiments, the cut gate structure 184 is made of dielectric material, such as oxide, silicon oxide, SiN, SiOCN, SiCN, SiOC, or another applicable material. In some embodiments, the cut gate structure 184 is formed by chemical vapor deposition (CVD), atomic layer deposition (ALD), another applicable method, or a combination thereof.

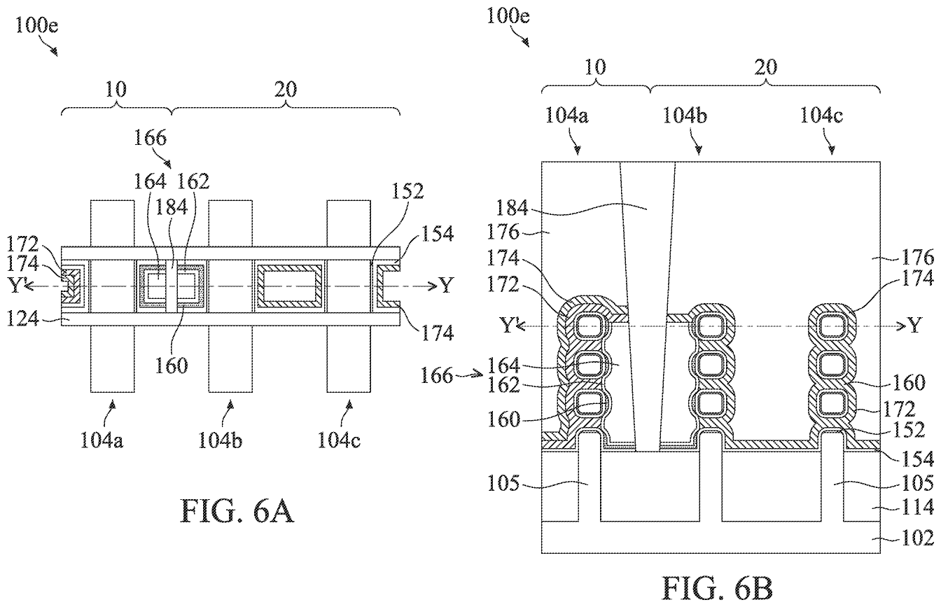

FIG. 6A show top view of a semiconductor structure 100e shown along plane Y-Y′ in FIG. 6B, in accordance with some embodiments. FIG. 6B shows a cross-sectional representation of the semiconductor device structure 100e along line Y-Y′ in FIG. 6A. The semiconductor structure 100e of FIGS. 6A-6B includes elements that are similar to, or the same as, elements of the semiconductor structure 100a of FIGS. 2A-2N-1 and 2A-2-2N-2.

As shown in FIGS. 6A and 6B, the cut gate structure 184 is formed between the first stack structure 104a and the second stack structure 104b, in accordance with some embodiments. The cut gate structure 184 passes through the dielectric wall 166, and the bottom surface of the cut gate structure 184 is lower than the top surface of the isolation structure 114.

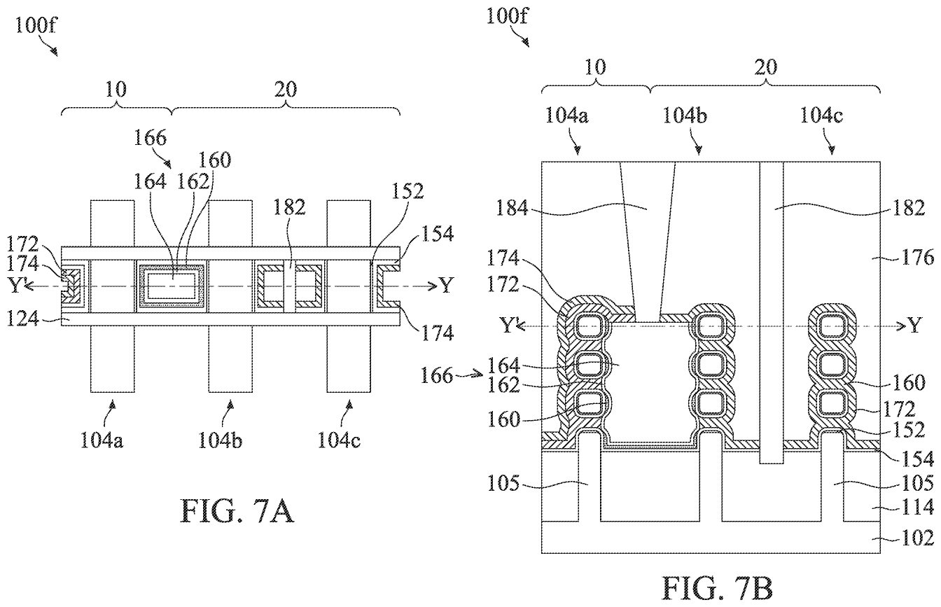

FIG. 7A show top view of a semiconductor structure 100f shown along plane Y-Y′ in FIG. 7B, in accordance with some embodiments. FIG. 7B shows a cross-sectional representation of the semiconductor device structure 100f along line Y-Y′ in FIG. 7A. The semiconductor structure 100f of FIGS. 7A-7B includes elements that are similar to, or the same as, elements of the semiconductor structure 100a of FIGS. 2A-2N-1 and 2A-2-2N-2.

As shown in FIGS. 7A and 7B, the deep isolation structure 182 is formed between the second stack structure 104b and the third stack structure 104c, and the cut gate structure 184 is formed between the first stack structure 104a and the second stack structure 104b. The bottom surface of the deep isolation structure 182 is lower than the bottom surface of the cut gate structure 184. The height of the deep isolation structure 182 is greater than the height of the cut gate structure 184.

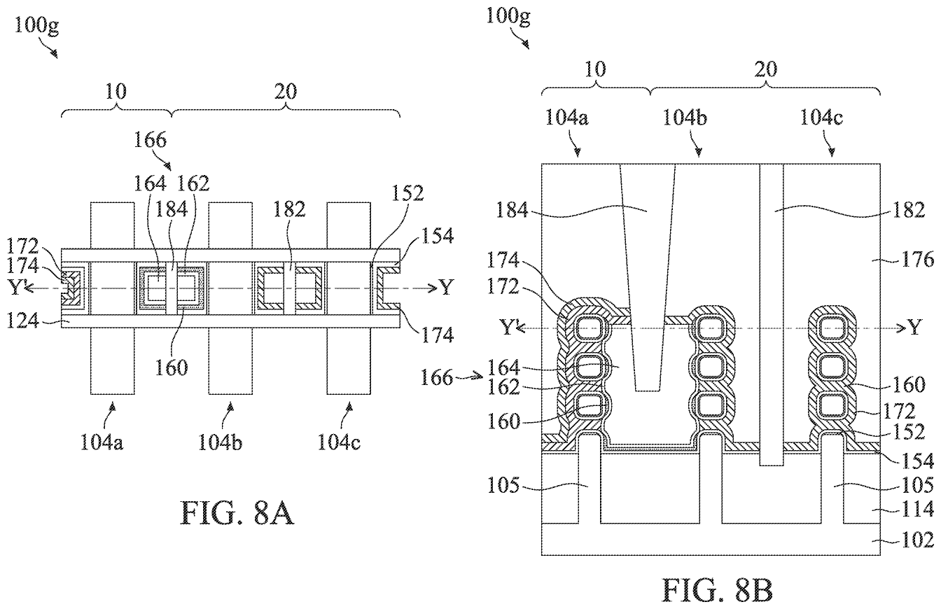

FIG. 8A show top view of a semiconductor structure 100g shown along plane Y-Y′ in FIG. 8B, in accordance with some embodiments. FIG. 8B shows a cross-sectional representation of the semiconductor device structure 100g along line Y-Y′ in FIG. 8A. The semiconductor structure 100g of FIGS. 8A-8B includes elements that are similar to, or the same as, elements of the semiconductor structure 100a of FIGS. 2A-2N-1 and 2A-2-2N-2.

As shown in FIGS. 8A and 8B, the deep isolation structure 182 is formed between the second stack structure 104b and the third stack structure 104c, and the cut gate structure 184 is formed between the first stack structure 104a and the second stack structure 104b. The bottom portion of the cut gate structure 184 is embedded in the dielectric wall 166.

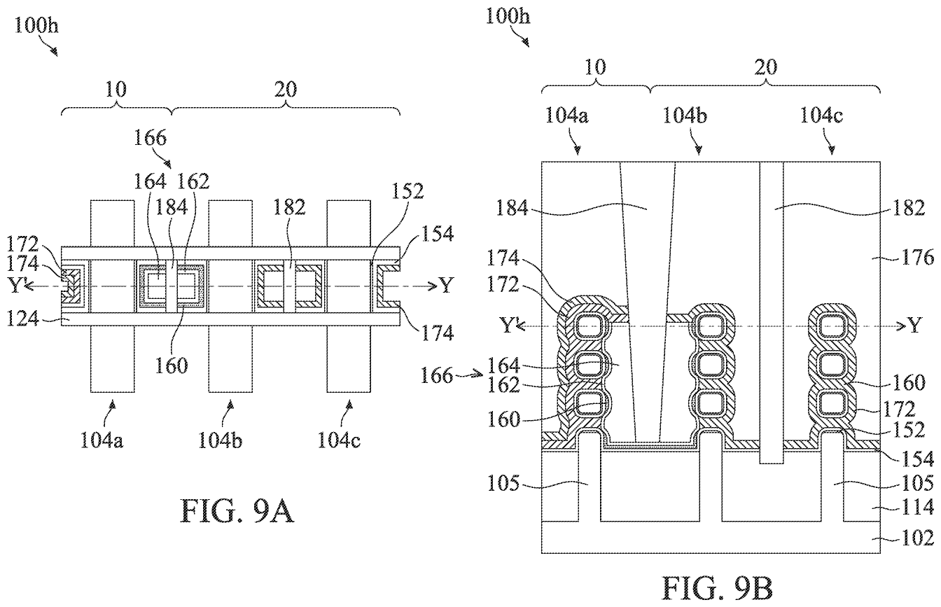

FIG. 9A show top view of a semiconductor structure 100h shown along plane Y-Y′ in FIG. 9B, in accordance with some embodiments. FIG. 9B shows a cross-sectional representation of the semiconductor device structure 100h along line Y-Y′ in FIG. 9A. The semiconductor structure 100h of FIGS. 9A-9B includes elements that are similar to, or the same as, elements of the semiconductor structure 100a of FIGS. 2A-2N-1 and 2A-2-2N-2.

As shown in FIGS. 9A and 9B, the deep isolation structure 182 is formed between the second stack structure 104b and the third stack structure 104c, and the cut gate structure 184 is formed between the first stack structure 104a and the second stack structure 104b. The cut gate structure 184 is through the dielectric wall 166, and the bottom surface of the cut gate structure 184 is in direct contact with the liner layer 160.

It should be noted that the semiconductor structures 100a-100h described above includes dielectric wall 166 is between the first stack structure 104a and the second stack structure 104b. The liner layer 160 is remaining between the dielectric wall 166 and the gate dielectric layer 154. The remaining liner layer 160 can reduce the parasitic capacitance of the semiconductor structure 100a-100h. Therefore, the performance of the semiconductor structure 100a-100h is improved.

It should be appreciated that the semiconductor structures 100a to 100h having the dielectric wall 166 between the first fin structure 104a and the second fin structure 104b, and the liner layer 160 connected to the gate dielectric layer 154 to the dielectric wall 166 described above may also be applied to FinFET structures, although not shown in the figures.

It should be noted that same elements in FIGS. 1A to 9B may be designated by the same numerals and may include similar or the same materials and may be formed by similar or the same processes; therefore such redundant details are omitted in the interest of brevity. In addition, although FIGS. 1A to 9B are described in relation to the method, it will be appreciated that the structures disclosed in FIGS. 1A to 9B are not limited to the method but may stand alone as structures independent of the method. Similarly, although the methods shown in FIGS. 1A to 9B are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes forming a first stack structure and a second stack structure over a substrate. A dielectric wall is formed between the first stack structure and the second stack structure. A liner layer is between the dielectric wall and the first stack structure. The space between the first stack structure and the second stack structure is filled with the dielectric wall to reduce the parasitic capacitance of the semiconductor structure. In addition, the remaining liner layer can also reduce the parasitic capacitance of the semiconductor structure. Therefore, the performance of the semiconductor structure is improved.

In some embodiments, a semiconductor structure is provided. The semiconductor structure includes a plurality of first nanostructures formed over a substrate, and a dielectric wall adjacent to the first nanostructures. The semiconductor structure also includes a first liner layer between the first nanostructures and the dielectric wall, and the first liner layer is in direct contact with the dielectric wall. The semiconductor structure also includes a gate structure surrounding the first nanostructures, and the first liner layer is in direct contact with a portion of the gate structure.

In some embodiments, a semiconductor structure is provided. The semiconductor structure includes a first fin structure formed over a substrate, and a plurality of first channels formed over the first fin structure. The semiconductor structure includes a gate dielectric layer formed over the first channels, and a liner layer formed on the gate dielectric layer. The semiconductor structure includes a dielectric wall adjacent to the first channels, and the dielectric wall is separated from the first channels by the gate dielectric layer and the liner layer.

In some embodiments, a method for forming a semiconductor structure is provided. The method includes forming a plurality of first nanostructures and a plurality of second nanostructures over a substrate. The method includes forming a liner layer on the first nanostructures and the second nanostructures, and forming a dielectric wall between the first nanostructures and the second nanostructures. The dielectric wall is in direct contact with the liner layer. The method includes removing a portion of the liner layer to expose a first gap between two adjacent first nanostructures and a second gap between two adjacent second nanostructures, and another portion of the liner layer is remaining between the first nanostructures and the dielectric wall. The method includes forming a first work function layer in the first gap, and forming a second work function layer over the first work function layer and in the second gap.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a plurality of first nanostructures formed over a substrate;
a dielectric wall adjacent to the first nanostructures;
a first liner layer between the first nanostructures and the dielectric wall, wherein the first liner layer is in direct contact with the dielectric wall; and
a gate structure surrounding the first nanostructures, wherein the first liner layer is in direct contact with a portion of the gate structure.

2. The semiconductor structure as claimed in claim 1, further comprising:
a plurality of second nanostructures adjacent to the first nanostructures; and
a second liner layer between the dielectric wall and the second nanostructures.

3. The semiconductor structure as claimed in claim 2, further comprising:
a plurality of third nanostructures adjacent to the second nanostructures; and
a deep isolation structure between the second nanostructures and the third nanostructures, wherein a top surface of the deep isolation structure is higher than a top surface of a topmost second nanostructure.

4. The semiconductor structure as claimed in claim 1, wherein the gate structure comprises a gate dielectric layer, and the gate dielectric layer is in direct contact with the first liner layer.

5. The semiconductor structure as claimed in claim 1, wherein the gate structure comprises a first work function layer, the first nanostructures are surrounded by the first work function layer, and a portion of the first work function layer is in direct contact with the dielectric wall.

6. The semiconductor structure as claimed in claim 5, wherein the gate structure comprises a second work function layer over the first work function layer, and a portion of the second work function layer is in direct contact with the dielectric wall.

7. The semiconductor structure as claimed in claim 1, wherein a portion of the first liner layer is directly below and in direct contact with the dielectric wall.

8. The semiconductor structure as claimed in claim 1, wherein a top surface of the dielectric wall is lower than a top surface of a topmost second nanostructure.

9. A semiconductor structure, comprising:
a first fin structure formed over a substrate;
a plurality of first channels formed over the first fin structure;
a gate dielectric layer formed over the first channels;
a liner layer formed on the gate dielectric layer; and
a dielectric wall adjacent to the first channels, wherein the dielectric wall is separated from the first channels by the gate dielectric layer and the liner layer.

10. The semiconductor structure as claimed in claim 1, further comprising:
a plurality of second channels adjacent to the first channels, wherein the dielectric wall is between the first channels and the second channels, and a top surface of the dielectric wall is lower than a top surface of a topmost second channel.

11. The semiconductor structure as claimed in claim 9, further comprising:
a first work function layer formed over the gate dielectric layer, wherein the first channels are surrounded by the first work function layer, and a portion of the first work function layer is in direct contact with a top surface of the dielectric wall.

12. The semiconductor structure as claimed in claim 9, wherein the dielectric wall is enclosed by the liner layer and the gate dielectric layer when seen from a top-view.

13. The semiconductor structure as claimed in claim 9, wherein the liner layer has a ring-shaped structure when seen from a top-view.

14. The semiconductor structure as claimed in claim 9, further comprising:
a cut gate structure formed over the dielectric wall, wherein a bottom surface of the cut gate structure is lower than a top surface of the dielectric wall.

15. The semiconductor structure as claimed in claim 9, wherein a bottommost surface of the liner layer is lower than a top surface of the first fin structure.

16. A method for forming a semiconductor structure, comprising:
forming a plurality of first nanostructures and a plurality of second nanostructures over a substrate;
forming a liner layer on the first nanostructures and the second nanostructures;
forming a dielectric wall between the first nanostructures and the second nanostructures, wherein the dielectric wall is in direct contact with the liner layer;
removing a portion of the liner layer to expose a first gap between two adjacent first nanostructures and a second gap between two adjacent second nanostructures, wherein another portion of the liner layer is remaining between the first nanostructures and the dielectric wall;
forming a first work function layer in the first gap; and
forming a second work function layer over the first work function layer and in the second gap.

17. The method for forming the semiconductor structure as claimed in claim 16, further comprising:
forming a gate dielectric layer on the first nanostructures and the second nanostructures before forming the liner layer, wherein the liner layer is between the gate dielectric layer and the dielectric wall.

18. The method for forming the semiconductor structure as claimed in claim 16, further comprising:
forming a spacer layer on the liner layer; and
forming a dielectric wall material on and in direct contact with the spacer layer, wherein the dielectric wall is constructed by the spacer layer and the dielectric wall material.

19. The method for forming the semiconductor structure as claimed in claim 16, further comprising:
forming a cut gate structure over the dielectric wall, wherein a bottom surface of the e cut gat structure is lower than a top surface of the dielectric wall.

20. The method for forming the semiconductor structure as claimed in claim 16, further comprising:
forming a deep isolation structure adjacent to the second nanostructures, wherein a top surface of the deep isolation structure is higher than a top surface of a topmost second nanostructure.
